(19) United States
(12) Patent Application Publication
(10) Pub. No.: US 2019/0307265 A1
(43) Pub. Date: Oct. 10, 2019

(54) VIDEO DISPLAY DEVICE FOR INTEGRATION INTO GONDOLA SHELVING

(71) Applicant: SYNQ ACCESS + SECURITY TECHNOLOGY LTD., Victoria (CA)

(72) Inventors: Nolan WHEELER, Victoria (CA); Joshua RODRIGUEZ, Victoria (CA); Chris STONIER, Victoria (CA); Chris MARTIN, Victoria (CA)

(21) Appl. No.: 16/376,285

(22) Filed: Apr. 5, 2019

(30) Foreign Application Priority Data
Apr. 5, 2018 (CA) 3000377

(51) Int. Cl. A47F 5/00; A47F 5/10; H05K 5/00; H05K 7/14

(52) U.S. Cl. CPC A47F 5/0043; H05K 7/14; H05K 5/0017; A47F 5/101

(57) ABSTRACT

There is provided a video display housing integrated within a gondola shelving unit. The gondola shelving unit has vertical uprights with receptacles for receiving shelving brackets. The video display housing is suspended by shelving brackets. The shelving brackets have engagement members which engage the receptacles in the vertical uprights of the gondola shelving unit to support the video display housing. The video display housing replaces a shelf on a gondola shelving unit. The retailer is able to rapidly remove and reconfigure the positioning of the video display housing, by removing the video display housing from one gondola shelving unit and replacing a shelf on another gondola shelving unit with the video display housing.

### FIELD

There is described a video display device with which to be integrated into gondola shelving.

### BACKGROUND

In the past, small televisions playing looped videos were placed on retail shelves. Digital signs in the form of video display devices are currently being used in retail establishments. These digital signs are generally hung from the ceiling via drop down mounts or fastened to structures within the retail establishment.

When speaking of retail shelving, a gondola shelving unit is a free standing fixture used by retailers to display merchandise. When a gondola shelving unit is placed perpendicular to a row of gondola shelving units it is termed an “end cap”. Coca-Cola has partnered with Google to provide digital end caps. These began as simple screens placed on coolers and end cap shelves, but has grown into fully built replacement end caps with both a digital screen and signage.

### SUMMARY

There is provided a video display housing integrated within a gondola shelving unit. The gondola shelving unit has vertical uprights with receptacles for receiving shelving brackets. The video display housing is suspended by shelving brackets. The shelving brackets have engagement members which engage the receptacles in the vertical uprights of the gondola shelving unit to support the video display housing.

The integration, described above, provides a retailer with the flexibility to place a video display housing in place of a shelf at any desired position on any of the gondola shelving units within the store. It also enables the retailer to rapidly remove and reconfigure the positioning of the video display housing, by removing the video display housing from one gondola shelving unit and replacing a shelf on another gondola shelving unit with the video display housing.

### BRIEF DESCRIPTION OF THE DRAWINGS

These and other features will become more apparent from the following description in which reference is made to the appended drawings, the drawings are for the purpose of illustration only and are not intended to be in any way limiting, wherein:

FIG. 1 is an exploded perspective view of a gondola shelving unit and video display housing integration.

FIG. 2 is a front elevation view of the combination illustrated in FIG. 1.

FIG. 3 is a side elevation view of the combination illustrated in FIG. 1.

FIG. 4 is a top plan view of the combination illustrated in FIG. 1.

### DETAILED DESCRIPTION

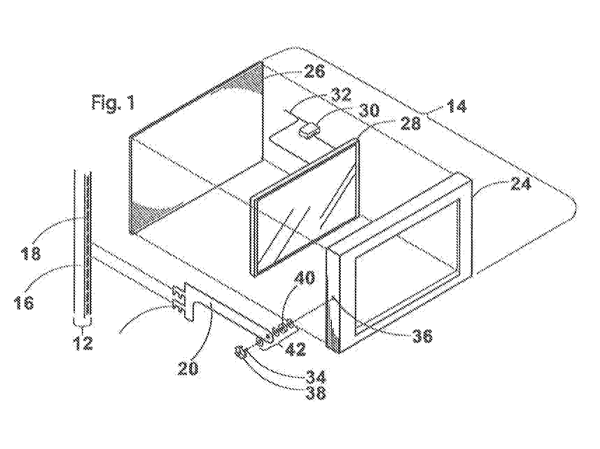

A video display housing integrated with a gondola shelving unit through use of shelving brackets will now be described with reference to FIG. 1 through FIG. 4.

### Structure and Relationship of Parts:

Referring to FIG. 1, there is illustrated a gondola shelving unit 12 and a video display housing 14. Gondola shelving unit 12 has vertical uprights 16 with receptacles 18 for receiving shelving brackets 20. Video display housing 14 is suspended by shelving brackets 20. Shelving brackets 20 having engagement members 22 which engage receptacles 18 in vertical uprights 16 of gondola shelving unit 12 to support video display housing 14.

Referring to FIG. 1, video display housing 14 consists of a front frame 24 and a back panel 26. Housed within video display housing 14 is at least one digital screen 28 (just one has been illustrated, but it will be appreciated that there could be more than one) and at least one media controller 30 (just one has been illustrated, but it will be appreciated that there could be one for each digital screen 28). A power connection is shown as power cord 32. The power connection of power cord 32 provides power to digital screen 28 and media controller 30. Media controller 30 controls the video output to digital screen 28. The connection between media controller 30 and digital screen 28 can be either wired or wireless. Media controller is encapsulated within the video display housing.

Referring to FIG. 1, video display housing 14 is coupled to shelving brackets 20 by a screw 34 which screws into a threaded opening 36 in video display housing 14. Screw 34 has an adjustment knob 38 that enables a user to release a clamping force, created by the torsion of screw 34, in order to effect an angular adjustment of video display housing 14 and then exert a clamping force through a series of spacers 40 and washers 42 to maintain video display housing 14 in the selected angular position.

### Operation:

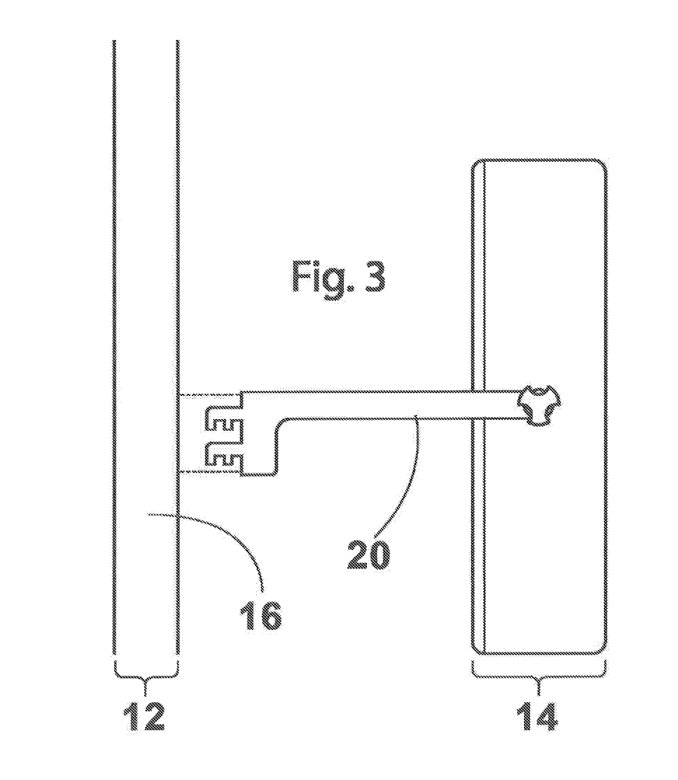

Referring to FIG. 3, shelving brackets 20 on video display housing 14 are engaged with vertical uprights 16 of gondola shelving unit 12. Referring to FIG. 1, engagement members 22 of shelving brackets 20 engage receptacles 18 in vertical uprights 16. The installation is very rapid. It is an installation that personnel who work with gondola shelving units are very familiar with, as it is the same connection used to connect shelves to the gondola shelving units. Video display housing 14 can just as easily be removed and repositioned, elsewhere on the gondola shelving unit or on a different gondola shelving unit.

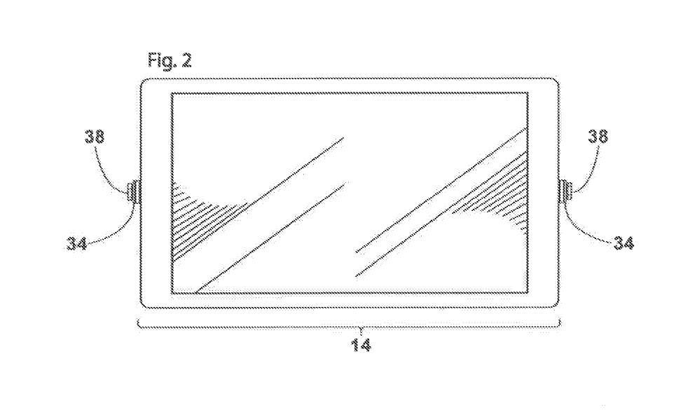

Referring to FIG. 2, there is shown a view a consumer would get of video display housing 14 if video display housing 14 were at eye level. Referring to FIG. 1, if an angular adjustment of video display housing 14 is required, this can be done during installation by means of adjustment knob 38 on screw 34, as described above.

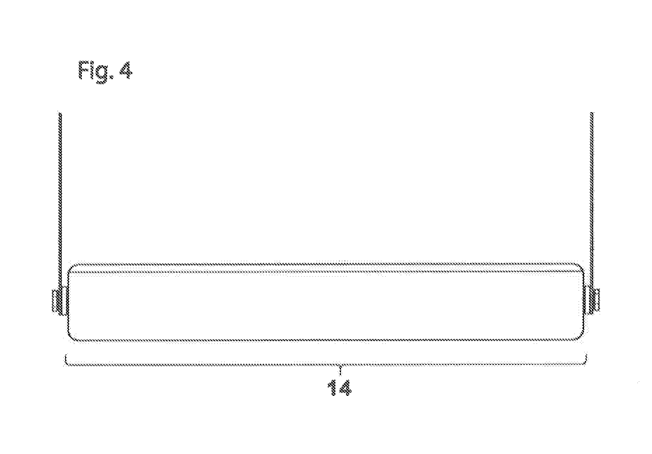

Referring to FIG. 1 and. FIG. 4, media controller 30 is encapsulated within video display housing 14. This prevents theft of or tampering with media controller 30.

In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be one and only one of the elements.

The scope of the claims should not be limited by the illustrated embodiments set forth as examples, but should be given the broadest interpretation consistent with a purposive construction of the claims in view of the description as a whole.

What is claimed is:

1. A video display housing suspended by shelving brackets, the shelving brackets having engagement members which engage receptacles in vertical uprights of gondola shelving unit.

2. The video display housing of claim 1, wherein the video display housing houses at least one digital screen, at least one media controller, and a power connection, whereby the power connection provides power to the at least one digital screen and the at least one media controller, with the media controller controlling the video output to the digital screen.

3. The video display housing of claim 2, wherein the media controller is encapsulated within the video display housing.

4. The video display housing of claim 1, in combination with a gondola shelving unit having vertical uprights with receptacles to receive engagement members of shelving brackets.
